(19) United States
(12) Patent Application Publication
(10) Pub. No.: US 2020/0005990 A1
(43) Pub. Date: Jan. 2, 2020

(54) STRUCTURES WITHIN A SUBSTRATE LAYER TO CURE MAGNETIC PASTE

(71) Applicant: Intel Corporation, Santa Clara, CA (US)

(72) Inventors: Sameer PAITAL, Chandler, AZ (US); Srinivas PIETAMBARAM, Gilbert, AZ (US); Yonggang LI, Chandler, AZ (US); Bai NIE, Chandler, AZ (US); Kristof DARMAWIKARTA, Chandler, AZ (US); Gang DUAN, Chandler, AZ (US)

(21) Appl. No.: 16/024,721

(22) Filed: Jun. 29, 2018

(51) Int. Cl. H01F 27/28; H01F 27/24; H01L 21/48; H01L 25/16; H01L 23/498; H01F 41/04; H01L 49/02

(52) U.S. Cl. CPC H01F 27/2804; H01F 27/24; H01L 21/4867; H01L 25/16; H01L 23/49838; H01F 27/324; H01L 21/4857; H01L 21/486; H01F 41/043; H01L 28/10; H01L 23/49822

(57) ABSTRACT

Embodiments herein relate to systems, apparatuses, or processes for embedding a magnetic core or a magnetic inductor in a substrate layer by applying a copper layer to a portion of the substrate layer, creating a structure in the substrate layer on top of at least part of the copper layer to identify a defined region within the substrate layer, and inserting a magnetic paste into the defined region where the copper layer identifies a side of the defined region and where the structure is to contain the magnetic paste within the defined region while the magnetic paste cures.

### FIELD

Embodiments of the present disclosure generally relate to the field of package assemblies, and in particular package assemblies that include magnetic cores.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIGS. 1A-1G illustrate an example of a package assembly using a dielectric cavity to position a magnetic core in contact with an inductor coil within the package at various stages of a manufacturing process, in accordance with embodiments.

FIGS. 2A-2K illustrate an example of a package assembly using a dielectric cavity to position an insulation layer between an inductor coil and a magnetic core within the package at various stages of a manufacturing process, in accordance with embodiments.

FIG. 3 illustrates an example of a process to insert magnetic paste into a defined region of a dielectric layer to contain the magnetic paste within the defined region while the magnetic paste cures, in accordance with embodiments.

FIGS. 4A-4G illustrate an example of a package assembly using a dam formation to position a magnetic core in contact with an inductor coil within a substrate at various stages of a manufacturing process, in accordance with embodiments.

FIGS. 5A-5G illustrate an example of a package assembly using a dam formation to position a magnetic core with dielectric layer as insulation between the inductor coil and magnetic core within the package at various stages of a manufacturing process, in accordance with embodiments

FIG. 6 illustrates an example of a process to insert magnetic paste into a defined region using a dam formation to contain the magnetic paste within the defined region while the magnetic paste cures, in accordance with embodiments.

FIG. 7 schematically illustrates a computing device, in accordance with embodiments.

### DETAILED DESCRIPTION

Embodiments of the present disclosure may generally relate to systems, apparatus, and/or processes directed to a manufacturing process flow for coreless substrates to paste print magnetic paste for inductors within a confined space inside the package. Embodiments may be directed to the creation of barriers in the form of cavities or dams within the substrate to hinder magnetic paste flow and thereby confine the magnetic paste to certain area and volume within the package. This may allow for greater predictability and precision in placing components, in particular magnetic cores, within a package. Additionally, embodiments related to manufacturing inductors within a package may experience an overall quality factor (Q factor) increase and package performance increase.

In legacy implementations, magnetic paste may overflow laterally during a paste printing process, the post paste printing bake process or some other paste curing process. In embodiments described herein, structures such as cavity and dam structures may facilitate printing the magnetic paste in a confined area within a substrate. As a result, a magnetic core may be precisely placed within the substrate. This may minimize parasitic effects by preventing the paste from getting too close to other conductive or nearby passive features due to the lack of control of the viscosity of the paste during manufacture.

Embodiments described herein may be directed to the manufacture of integrated circuits (ICs), memory, micro-electro-mechanical systems (MEMS), optics, and other packages and/or components to support improved functionality, reduced form factor, and increased efficiency for supplying and managing power from a power source to these components. In embodiments, this may result in a higher density of passive elements, for example inductors and capacitors, within these components.

Embodiments described herein may include manufacturing techniques manufacturing approach to paste print magnetics within a confined space inside a coreless substrate package to improve the quality factor and thereby performance. It will have significant advantage in power management and performance of devices aimed at reduced form factor and higher functionality such as mobile applications, wearables, Internet of things (IoT), and the like.

In legacy implementations, passive components are surface mounted as individual discrete components close that are close to active components on a package or on a board. The proximity of these passives to the actives degrades product performance due to high parasitics, and the size of these passives may make it difficult to continue to miniaturize packages.

In other legacy implementations, plated through holes (PTH) were created in a substrate core material, with magnetic paste plugged inside the PTH. The substrate core material provided mechanical, thermal, and dimensional stability during the paste plugging process. However, these implementations were not suitable for coreless substrate package architectures used, for example, to reduce the Z-height of a package.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

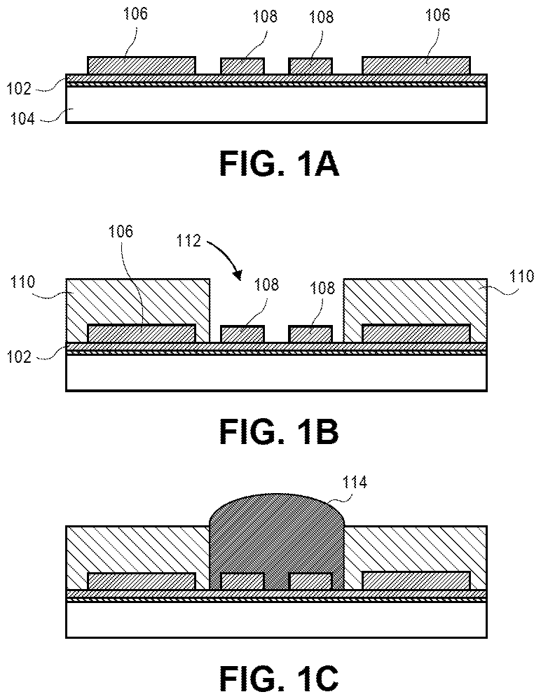

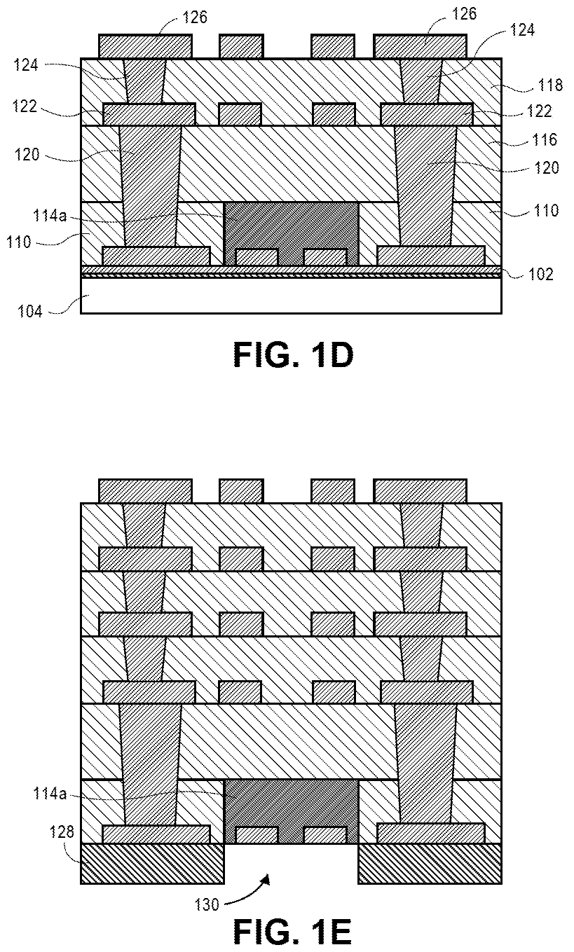

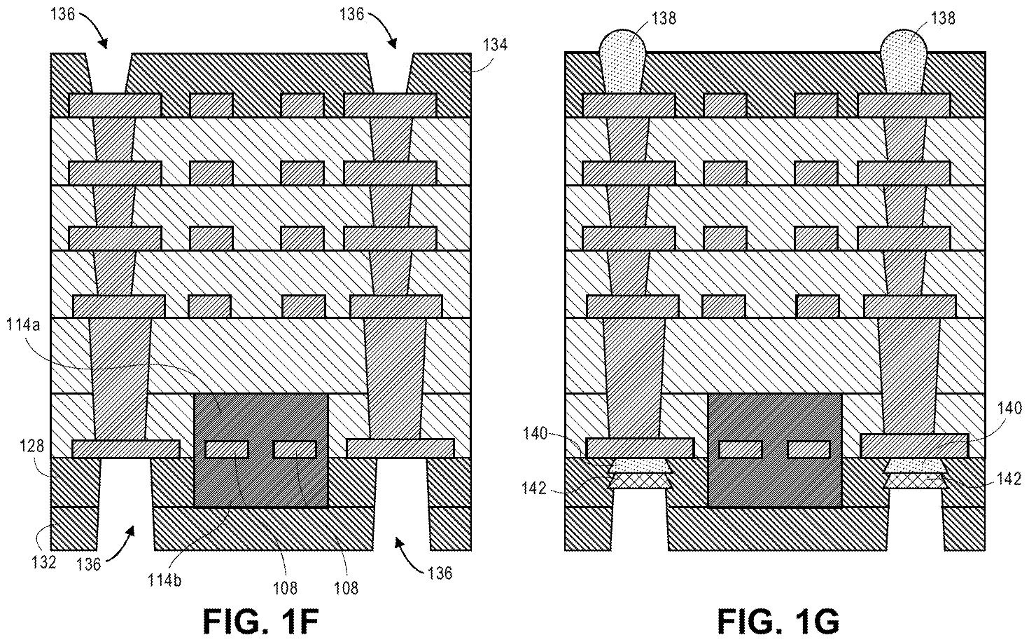

FIGS. 1A-1G illustrate an example of a package assembly using a dielectric cavity to position a magnetic core in contact with an inductor coil within the package at various stages of a manufacturing process, in accordance with embodiments. FIG. 1A shows patterning of a copper (Cu) inductor coil 108 on a substrate 104. The substrate 104 may be carrier substrate sacrificed later on in the manufacturing process. A Cu layer 102, as well as other Cu features 106 that may include CU patterns layers with pads and traces for interconnecting Via landings subsequently in the manufacturing process may be placed upon the substrate 104.

In embodiments, the inductor coil 108 may be formed by a semi-additive patterning process (SAP), that may include lithography patterning of photoresist film on the substrate 104, followed by Cu plating and resist strip to achieve a winding coplanar single Cu inductor coil 108 structure.

FIG. 1B shows a dielectric layer 110 that may be applied to the Cu layer 102, Cu features 106, and inductor coil 108. In embodiments, the dielectric material may be a low dielectric constant (low K) dielectric material such as Ajinomoto Build-up Film (ABF). A cavity 112 may be created to expose the inductor coil 108 structure. The cavity 112 may be created through laser skiving, laser drilling, etching, or through some other suitable process. The Cu features 106 may be used for alignment to facilitate the accuracy of cavity 112 creation.

FIG. 1C shows a magnetic paste 114, which also may be referred to in embodiments as magnetic plug paste or magnetic core paste, inserted into the cavity 112. The magnetic paste 114 may be inserted into the cavity 112 in such a way that it comes in to direct physical contact with substantially all of the Cu layer 102 and/or of the inductor coil 108.

In embodiments, the magnetic paste 114 may include commercially available iron-cobalt (Fe—Co) and iron-nickel (Fe—Ni) based nano ferromagnetic alloy powders. In embodiments, nano flakes of CoFe₂O₄, CoNiFe, NiFeMo and/or NiFe can be used as precursor material for the magnetic core. These alloy systems have a very narrow hysteresis loop with almost zero coercive magnetic field. These properties may be desirable for inductor applications due to little to no hysteresis loss. The precursor material may be mixed using adjustable amount of carrier polymers such as epoxy resins and an organic solvent and may create a thick and/or viscous slurry for plugging inside the cavity 112 using a stencil based printer or inkjet printer. The Fe—Co and Fe—Ni alloys may have a permeability as high as >1000, and maybe expected to deliver permeability as high as >100 when composited with a bonding materials such as epoxy, polyimide, etc. For stencil-based printing, process parameters such as squeezing pressure and speed, viscosity of slurry, curing temperature and mask pattern accuracy control the plugging morphology of the core inside the confined space. Printing accuracy with stencil printing can be achieved with alignment of fiducials using an attached camera system and thereby calculating compensation for any incoming shrinkage or scaling.

FIG. 1D shows the magnetic core 114a that results from the magnetic paste 114 being cured and planarized or ground down to a predetermined depth to remove excess or overflowed magnetic paste and/or to reduce the thickness variation of the dielectric layer 110.

In addition, using SAP or some other suitable process, additional build-up on the substrate 104 may occur. SAP process flow, for example via drill, desmear, Cu seed layer deposit, dry film resist (DFR) patterning, Cu plating, resist strip application and Cu seed etch may be carried out to form additional build-up layers. For example, dielectric buildup layers 116, 118 may be added, filled Vias 120, 124 may be added, and/or other Cu features 122, 126 may be added. Other routing, pad, or other package features (not shown) may be added.

FIG. 1E shows the substrate 104 and the Cu layer 102 of FIG. 1D removed to prepare for a second magnetic core integration. A solder resist (SR) layer 128 may be applied proximate to the magnetic core 114a, with a cavity 130 removed within the SR layer 128.

FIG. 1F shows the result of the second magnetic core 114b after magnetic paste (not shown) was inserted into the cavity 130, and later planarized to ground down in a manner similar to FIG. 1D. as a result, the inductor coil structure 108 may be encased in the first magnetic core 114a and the second magnetic core 114b. A second SR layer 132 may be applied adjacent to the first SR layer 128, and a third SR layer 134 may be applied to the opposite side.

In embodiments, vias 136 may be drilled to form first level interconnect and/or second level interconnect vias.

FIG. 1G shows micro balls 138, as well as connectors 140, 142 applied into the vias 136. In embodiments, the micro balls 138 and connectors 140, 142 may be made of nickel, palladium, and/or gold, or of some other conductive metal or material.

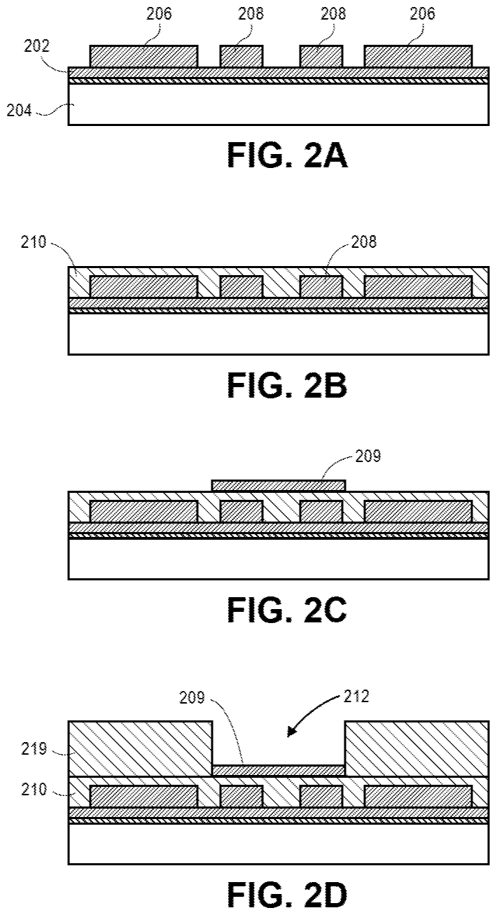

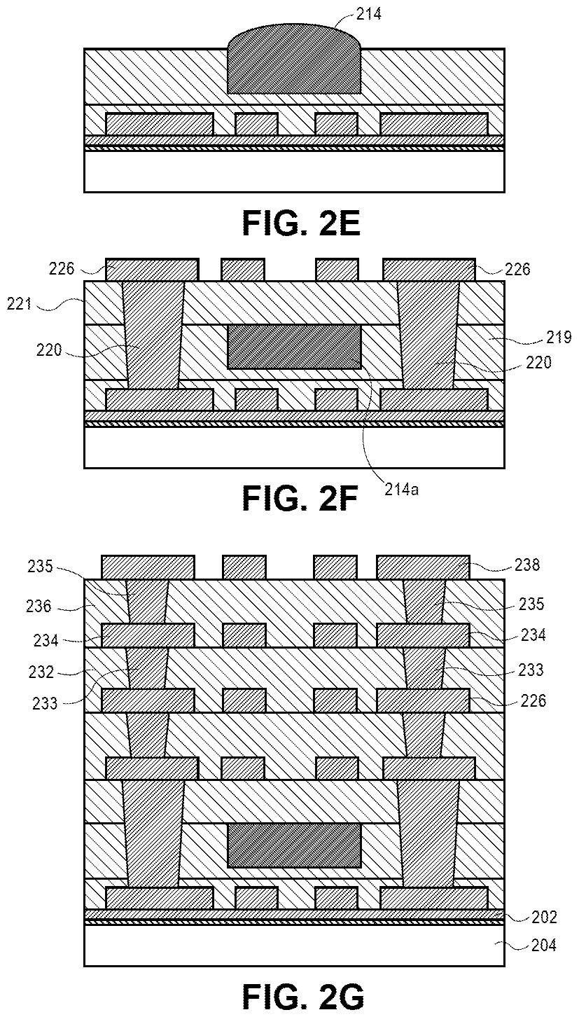

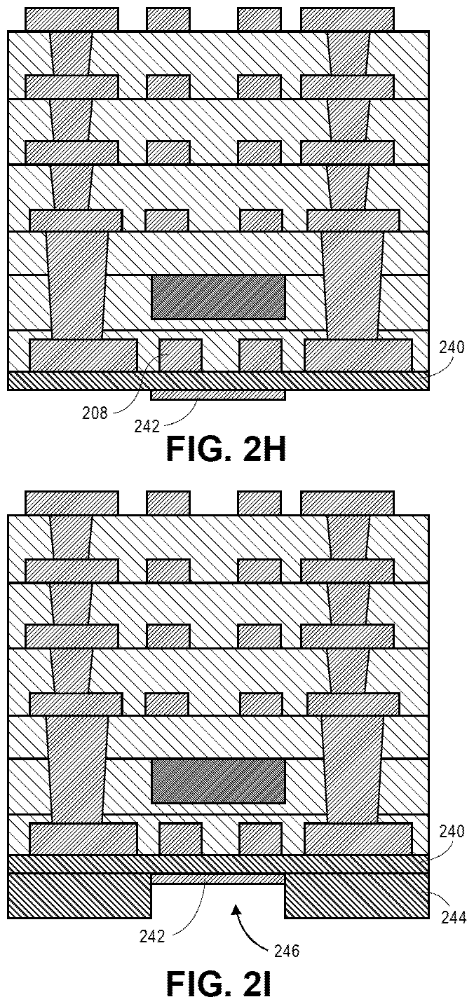

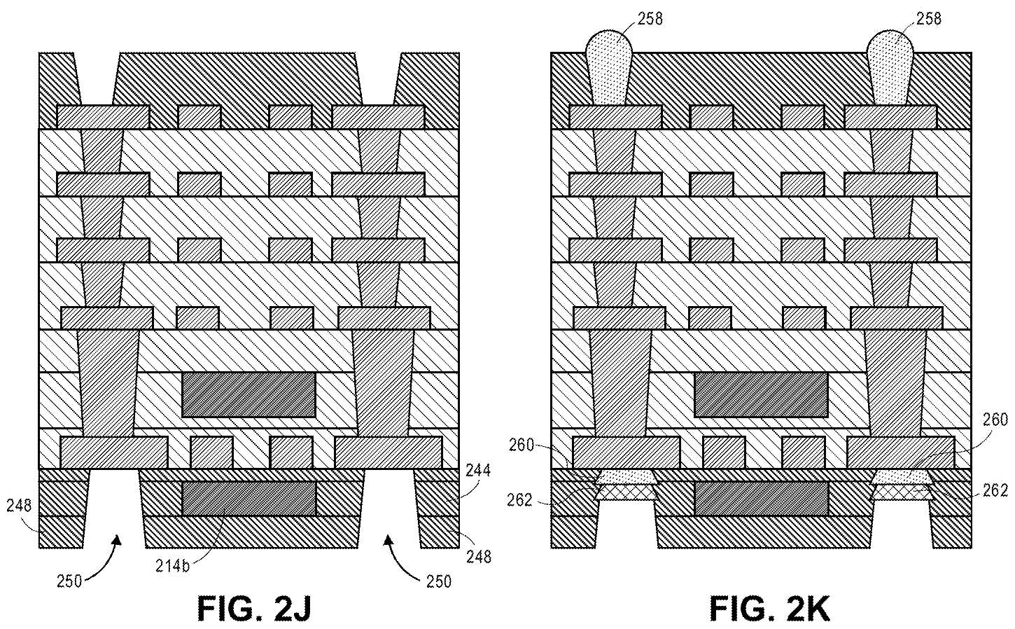

FIGS. 2A-2K illustrate an example of a package assembly using a dielectric cavity to position an insulation layer between an inductor coil and a magnetic core within the package at various stages of a manufacturing process, in accordance with embodiments. In embodiments, the position of the insulation layer may offset degradation in inductor performance due to eddy current loss, electromagnetic interference (EMI) noise, and/or other parasitics.

FIG. 2A shows patterning of a copper (Cu) inductor coil 208 on a substrate 204. The substrate 204 may be carrier substrate sacrificed later on in the manufacturing process. A Cu layer 202, as well as other Cu features 206 that may include CU patterns layers with pads and traces for interconnecting Via landings subsequently in the manufacturing process may be placed upon the substrate 204.

In embodiments, the inductor coil 208 may be formed by a semi-additive patterning process (SAP), that may include lithography patterning of photoresist film on the substrate 204, followed by Cu plating and resist strip to achieve a winding coplanar single Cu inductor coil 208 structure.

FIG. 2B shows a dielectric layer 210 that may be applied to the Cu layer 202, Cu features 206, and inductor coil 208. In embodiments, the dielectric material may be a low K dielectric material such as ABF. The thickness of the dielectric layer 210 will determine the space between the inductor coil 208 and the magnetic core.

FIG. 2C shows the patterning of a Cu etch stop 209 on a surface of the dielectric layer 210. The area of the etch stop 209 may determine the footprint of the magnetic core.

FIG. 2D shows a second dielectric layer 219 applied on top of the dielectric layer 210 and the etch stop 209. In embodiments, the second dielectric layer 219 may be thicker than the dielectric layer 210. A cavity 212 may be created in second dielectric layer 219, and may expose the etch stop 209. In embodiments, the cavity 212 may be created by laser drilling, or by some other suitable process.

FIG. 2E shows the etch stop 209 as etched away using an etching process. A magnetic paste 214 may be inserted in the cavity 212.

FIG. 2F shows the magnetic core 214a that results from the magnetic paste 214 being cured and planarized or ground down to a predetermined depth to remove excess or overflowed magnetic paste and/or to reduce the thickness variation of the second dielectric layer 219.

In addition, using SAP or some other suitable process, additional build-up on the substrate 204 may occur. SAP process flow, for example via drill, desmear, Cu seed layer deposit, DFR patterning, Cu plating, resist strip application and Cu seed etch may be carried out to form additional build-up layers. For example, dielectric buildup layer 221, may be added, filled Vias 220 may be added, and/or other Cu features 226 may be added. Other routing, pad, or other package features (not shown) may be added.

FIG. 2G shows additional build-up layers that may include additional dielectric layers 232, 236, additional vias 233, 235, and additional Cu features 234, 238.

FIG. 2H shows substrate 204, as a carrier substrate, and the Cu layer 202 removed and a first SR layer 240 applied. In addition, a Cu etch stop 242 may be applied. In embodiments, the etch stop 242 may be positioned proximate to the inductor coil 208.

FIG. 2I shows a second SR layer 244 that may be applied on top of the first SR layer 240 and the etch stop 242. A cavity 246 may be removed in the second SR layer 244, and may expose the etch stop 242.

FIG. 2J shows a second magnetic inductor core 214b that has been placed in cavity 246. In embodiments, a process similar to that shown above in FIG. 2E-2F may be used. A third SR layer 248 may be applied on top of the second layer 244 and the second magnetic inductor core 214b. In embodiments, vias 250 may be drilled.

FIG. 2K shows micro balls 258, as well as connectors 260, 262 applied into the vias 250. In embodiments, the micro balls 258 and connectors 260, 262 may be made of nickel, palladium, and/or gold, or of some other conductive metal or material.

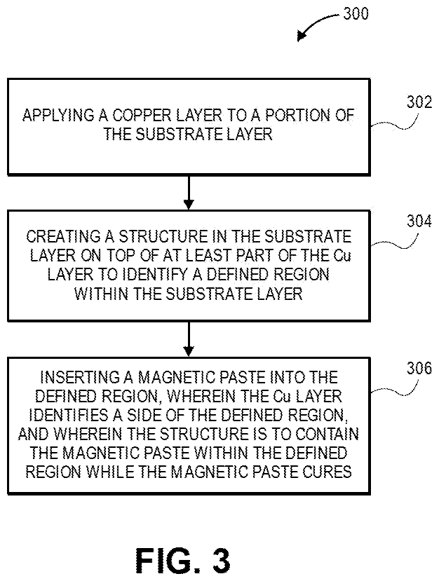

FIG. 3 illustrates an example of a process to insert magnetic paste into a defined region of a dielectric layer to contain the magnetic paste within the defined region while the magnetic paste cures, in accordance with embodiments. Process 300 may be performed by one or more elements, techniques, or systems that may be found in FIG. 1A-2K.

At block 302, the process may include applying a copper (Cu) layer to a portion of the substrate layer. In embodiments, the Cu layer may be similar to Cu layer 102 of FIG. 1A or Cu layer 202 of FIG. 2A. In embodiments, the Cu layer 102, 202 may include any conductive metal, and may be applied by an electroless, sputtering, or other technique.

At block 304, the process may include creating a structure in the substrate layer on top of at least part of the Cu layer to identify a defined region within the substrate layer. In embodiments, the CU layer may be similar to Cu layer 102, 202. The defined region may be similar to cavity 112 and the substrate layer may be similar to substrate 110 of FIG. 1B, or the defined region may be similar to cavity 130 and the substrate layer may be similar to SR layer 128 of FIG. 1E.

In embodiments, the defined region may be similar to cavity 212 and the substrate layer may be similar to substrate 219 of FIG. 2D, or the defined region may be similar to cavity 246 and the substrate layer may be similar to SR layer 244 of FIG. 2I.

At block 306, the process may include inserting a magnetic paste into the defined region, wherein the Cu layer identifies a side of the defined region, and wherein the structure is to contain the magnetic paste within the defined region while the magnetic paste cures. In embodiments, the magnetic paste may be similar to magnetic paste 114 of FIG. 1C or magnetic paste 114b of FIG. 1F.

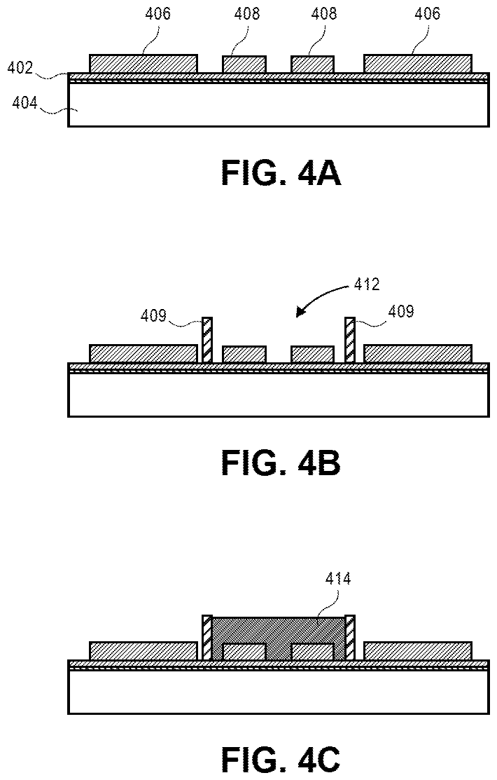

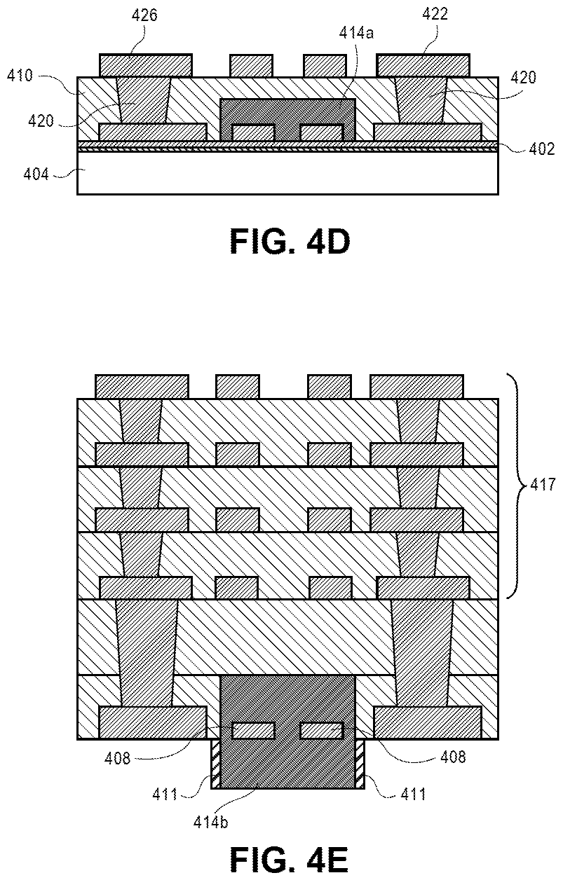

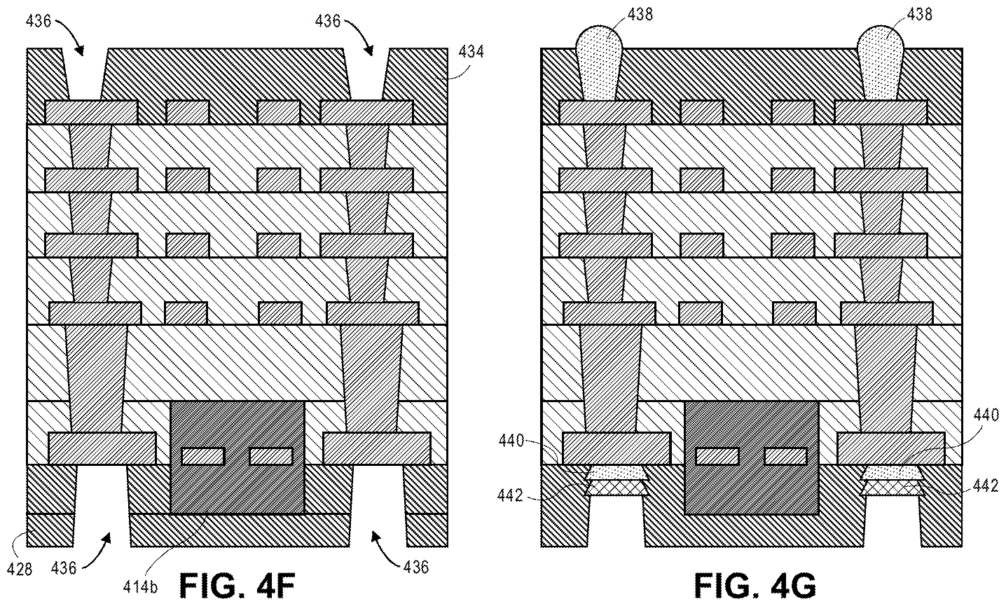

FIGS. 4A-4G illustrate an example of a package assembly using a dam formation to position a magnetic core in contact with an inductor coil within a substrate at various stages of a manufacturing process, in accordance with embodiments. In embodiments, dam formation may be accomplished based on an inkjet-based printing approach.

FIG. 4A shows patterning of a Cu inductor coil 408 on a substrate 404. The substrate 404 may be carrier substrate sacrificed later on in the manufacturing process. A Cu layer 402, as well as other Cu features 406 that may include Cu patterns layers with pads and traces for interconnecting Via landings subsequently in the manufacturing process may be placed upon the substrate 404.

FIG. 4B shows dams 409 attached to the Cu layer 402. In embodiments, an SR or other photo definable type dielectric paste may be used for creating dams 409 or dam-like features. In embodiments, high aspect ratio dam-like features of approximately 500 μm in height and/or 100 μm in width may be achieved using commercially available inkjet printers. As a result of creating dams 409, a cavity 412 may be created.

FIG. 4C shows magnetic paste 414 that is placed between the dams 409. In embodiments, after the dams 409 are created and cured, a similar inkjet-based paste printing technique may be used to print the magnetic paste 414 within the cavity 412.

FIG. 4D shows a dielectric layer 410 placed on the Cu layer 402 and surrounding the cured magnetic core 414a. In embodiments, the dams 409 may be stripped away before the dielectric layer 410 is applied. In embodiments, filled through holes vias 420 may be created in the dielectric layer 410, and/or other Cu features 422, 426 may be added. Other routing, pad, or other package features (not shown) may be added.

FIG. 4E shows the substrate 404 stripped away, and the Cu layer 402 etched away. Dams 411 are printed on a surface proximate to the Cu inductor coil 408, and magnetic paste 414 may be inserted between the dams 411.

In addition, using SAP or some other suitable process, additional build-up 417 on the substrate 404 may occur. SAP process flow, for example via drill, desmear, Cu seed layer deposit, DFR patterning, Cu plating, resist strip application and Cu seed etch may be carried out to form additional build-up layers.

FIG. 4F shows the result of the second magnetic core 414b after the dams 411 are stripped away. As a result, the inductor coil structure 408 may be encased in the first magnetic core 414a and the second magnetic core 414b. A SR layer 428 may be applied adjacent to the second magnetic core 414b, and a second SR layer 434 may be applied to the opposite side.

In embodiments, vias 436 may be drilled to form first level interconnect and/or second level interconnect vias.

FIG. 4G shows micro balls 438, as well as connectors 440, 442 applied into the vias 436. In embodiments, the micro balls 438 and connectors 440, 442 may be made of nickel, palladium, and/or gold, or of some other conductive metal or material.

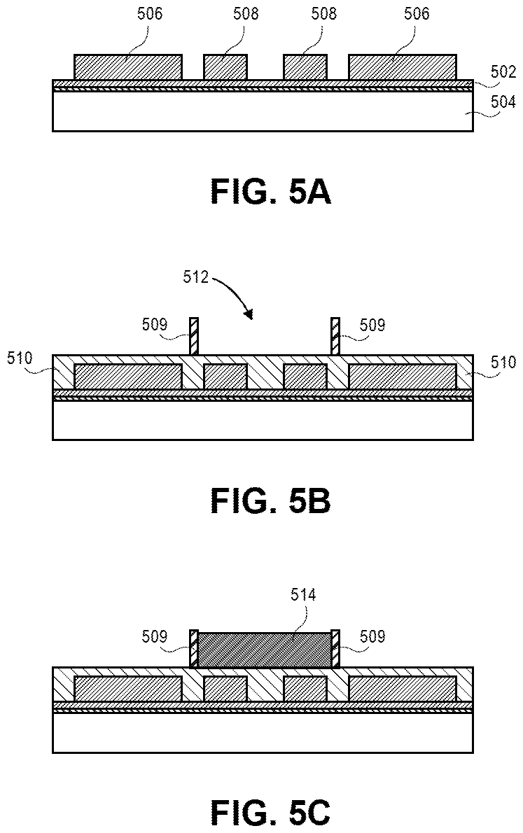

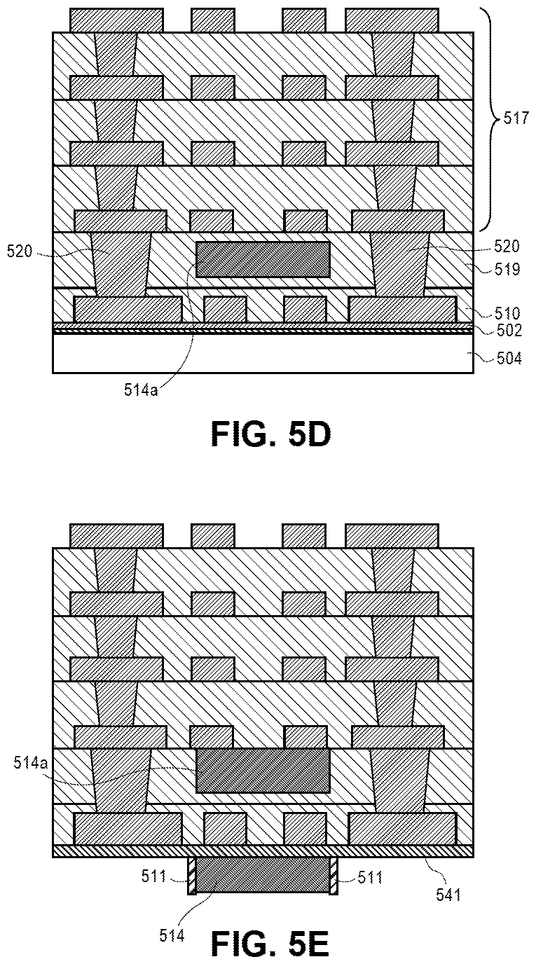

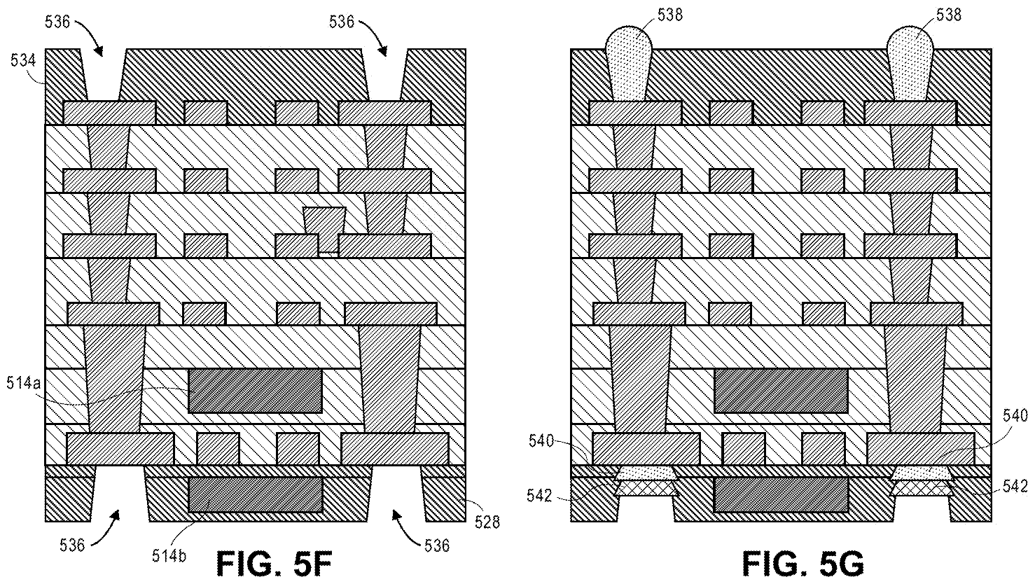

FIGS. 5A-5G illustrate an example of a package assembly using a dam formation to position a magnetic core with a dielectric layer as insulation between the inductor coil and magnetic core within the package at various stages of a manufacturing process, in accordance with embodiments.

FIG. 5A shows patterning of a copper (Cu) inductor coil 508 on a substrate 504. The substrate 504 may be carrier substrate sacrificed later on in the manufacturing process. A Cu layer 502, as well as other Cu features 506 that may include Cu patterns layers with pads and traces for interconnecting Via landings subsequently in the manufacturing process may be placed upon the substrate 504.

In embodiments, the inductor coil 508 may be formed by a SAP, process that may include lithography patterning of photoresist film on the substrate 504, followed by Cu plating and resist strip to achieve a winding coplanar single Cu inductor coil 508 structure.

FIG. 5B shows a dielectric layer 510 that may be applied to the Cu layer 502, Cu features 506, and inductor coil 508. In embodiments, the dielectric material may be a low K dielectric material such as ABF. The thickness of the dielectric layer 510 will determine the space between the inductor coil 508 and the magnetic core.

Dams 509 may then be applied to the dielectric layer 510 to create a cavity 512. As described above, the dams 509 may be created using an inkjet printing technique using a SR or other photo definable type dielectric paste.

FIG. 5C shows magnetic paste 514 that is placed between the dams 509. In embodiments, after the dams 509 are created and cured, a similar inkjet-based paste printing technique may be used to print the magnetic paste 514 within the cavity 512.

FIG. 5D shows a second dielectric layer 519 applied on top of the dielectric layer 510. Filled Vias 520 may be added. In addition, using SAP or some other suitable process, additional build-up 517 on the second dielectric layer 519 may occur. SAP process flow, for example via drill, desmear, Cu seed layer deposit, DFR patterning, Cu plating, resist strip application and Cu seed etch may be carried out to form additional build-up layers. Other routing, pad, or other package features (not shown) may be added.

FIG. 5E shows the substrate 504 stripped away, and the Cu layer 502 etched away. An SR layer 541 may be applied. Dams 511 may then be applied to the SR layer 541. Dams 511 may be created using inkjet printing techniques as described above. Magnetic paste 514 may then be inserted between the dams 511.

FIG. 5F shows the result of the second magnetic core 514b after the dams 511 are stripped away. As a result, the inductor coil structure 508 may adjacent to but not in physical contact with the first magnetic core 514a and the second magnetic core 514b. A SR layer 528 may be applied adjacent to the second magnetic core 514b, and a second SR layer 534 may be applied to the opposite side.

In embodiments, vias 536 may be drilled to form first level interconnect and/or second level interconnect vias.

FIG. 5G shows micro balls 538, as well as connectors 540, 542 applied into the vias 536. In embodiments, the micro balls 538 and connectors 540, 542 may be made of nickel, palladium, and/or gold, or of some other conductive metal or material.

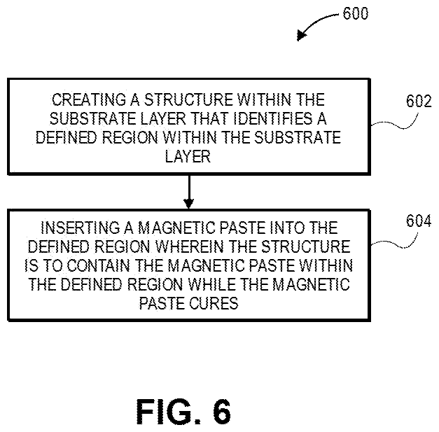

FIG. 6 illustrates an example of a process to insert magnetic paste into a defined region using a dam formation to contain the magnetic paste within the defined region while the magnetic paste cures, in accordance with embodiments. Process 600 may be performed by one or more elements, techniques, or systems that may be found in FIG. 4A-5G.

At block 602, the process may include creating a structure within the substrate layer that identifies a defined region within the substrate layer. In embodiments, the substrate layer may be similar to the layer containing Cu features 406 and inductor coil 408 of FIG. 4A. The structure may be similar to dams 409 of FIG. 4B with the defined region similar to cavity 412. In embodiments, the substrate layer may be similar to the layer above layer 510 of FIG. 5B, that includes the structure that may be similar to dams 509 that form the defined cavity 512.

At block 604, the process may include inserting a magnetic paste into the defined region, wherein the structure is to contain the magnetic paste within the defined region while the magnetic paste cures. In embodiments, the defined region may be similar to cavity 412 of FIG. 4B, and the magnetic paste may be similar to magnetic paste 414 of FIG. 4C. In embodiments, the substrate layer may be similar to the layer above layer 510 of FIG. 5B, and the magnetic paste may be similar to magnetic paste 514.

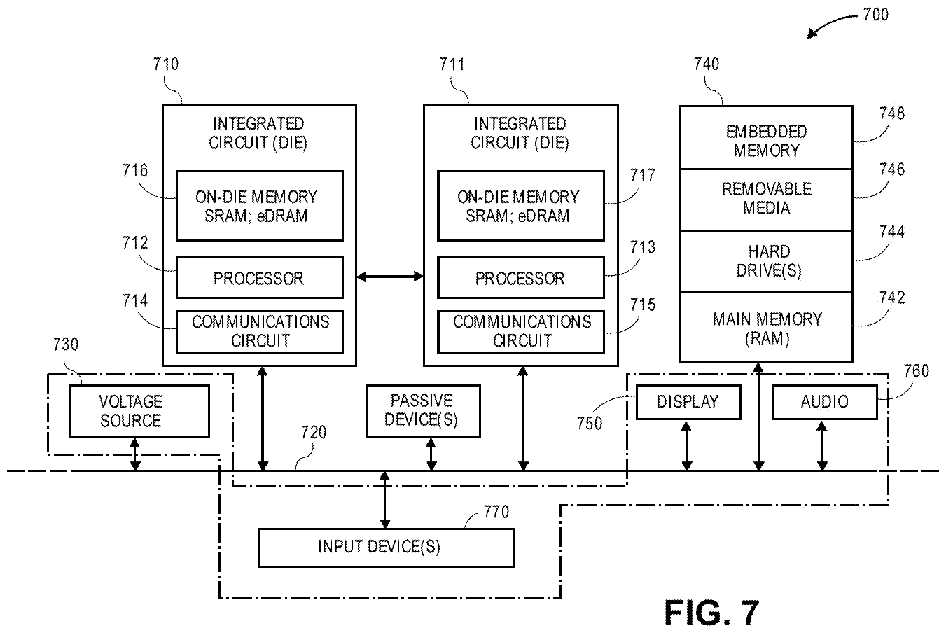

FIG. 7 schematically illustrates a computing device, in accordance with embodiments. The computer system 700 (also referred to as the electronic system 700) as depicted can embody magnetic cores cured using structures within a substrate layer, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, magnetic cores cured using structures within a substrate layer, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having magnetic cores cured using structures within a substrate layer, according to any of the several disclosed embodiments and their equivalents, an electronic system, a computer system, one or more methods of fabricating an integrated circuit, and one or more methods of fabricating an electronic assembly that includes a package substrate having magnetic cores cured using structures within a substrate layer, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having magnetic cores cured using structures within a substrate layer embodiments and their equivalents. A foundation substrate may be included, as represented by the dashed line of FIG. 7. Passive devices may also be included, as is also depicted in FIG. 7.

### Examples

Example 1 may be a package comprising: a substrate having a first side and a second side opposite the first side; and an inductor embedded within the substrate, wherein the inductor is disposed between a first substrate layer adjacent to the first side of the substrate and a second substrate layer adjacent to the second side of the substrate.

Example 2 may be the package of example 1, wherein the substrate is a coreless substrate.

Example 3 may be the package of example 1, wherein the inductor includes a magnetic core and a copper (Cu) winding inductor structure.

Example 4 may be the package of example 3, wherein the magnetic core includes at least one of: a Fe—Co or Fe—Ni based nano ferromagnetic alloy powder, or nano flakes that include CoFe2O4, CoNiFe, NiFeMo or NiFe.

Example 5 may be the package of example 3, wherein the magnetic core is in physical contact with the Cu winding inductor structure.

Example 6 may be the package of example 1, wherein the magnetic core comprises two coupled magnetic cores.

Example 7 may be the package of any one of examples 1-6, further comprising a die coupled to the first side of the substrate.

Example 8 may be a method for embedding a magnetic inductor in a substrate layer, the method comprising: creating a structure within the substrate layer that identifies a defined region within the substrate layer; inserting a magnetic paste into the defined region; and wherein the structure is to contain the magnetic paste within the defined region while the magnetic paste cures.

Example 9 may be the method of example 8, wherein the substrate layer includes one or more conductive features; and wherein the magnetic paste is to physically contact only a subset of the one or more conductive features that are within the defined region.

Example 10 may be the method of example 9, wherein the conductive features include a winding inductor structure or part thereof.

Example 11 may be the method of any one of examples 8-10, wherein creating a structure within the substrate layer further comprises: applying a dielectric layer in the substrate layer; and creating a cavity within the dielectric layer, wherein the cavity is the defined region.

Example 12 maybe the method of example 11, wherein the substrate layer includes a copper seed layer below the dielectric layer; and wherein creating the cavity further includes laser drilling a portion of the dielectric layer to create the cavity.

Example 13 may be the method of example 12, further comprising removing the copper seed layer.

Example 14 may be the method of example 8, wherein creating the structure within the substrate further comprises: creating a dam structure using inkjet printing.

Example 15 may be the method of example 14, wherein the dam structure includes a solder resist material; and further comprising curing or partially curing the dam structure with ultraviolet light.

Example 16 maybe the method of example 8, further comprising removing the structure.

Example 17 may be a method for embedding a magnetic inductor in a substrate layer, the method comprising: applying a copper (Cu) layer to a portion of the substrate layer; creating a structure in the substrate layer on top of at least part of the Cu layer to identify a defined region within the substrate layer; inserting a magnetic paste into the defined region; wherein the Cu layer identifies a side of the defined region; and wherein the structure is to contain the magnetic paste within the defined region while the magnetic paste cures.

Example 18 may be the method of example 17, wherein creating a structure to contain the magnetic paste further comprises: applying a dielectric layer in the substrate layer; and creating a cavity within the dielectric layer, wherein the cavity is the defined region.

Example 19 may be the method of example 18, wherein creating the cavity further includes laser drilling a portion of the dielectric layer to create the cavity.

Example 20 may be the method of example 17, wherein creating the structure further comprises: creating a dam structure above the Cu layer using inkjet printing, wherein the dam structure includes a solder resist material; and curing or partially curing the dam structure using ultraviolet light.

The following paragraphs describe examples of various embodiments.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a substrate having a first side and a second side opposite the first side; and
an inductor embedded within the substrate, wherein the inductor is disposed between a first substrate layer adjacent to the first side of the substrate and a second substrate layer adjacent to the second side of the substrate.

2. The package of claim 1, wherein the substrate is a coreless substrate.

3. The package of claim 1, wherein the inductor includes a magnetic core and a copper (Cu) winding inductor structure.

4. The package of claim 3, wherein the magnetic core includes at least one of: a Fe—Co or Fe—Ni based nano ferromagnetic alloy powder, or nano flakes that include CoFe₂O₄, CoNiFe, NiFeMo or NiFe.

5. The package of claim 3, wherein the magnetic core is in physical contact with the Cu winding inductor structure.

6. The package of claim 1, wherein the magnetic core comprises two coupled magnetic cores.

7. The package of claim 1, further comprising a die coupled to the first side of the substrate.

8. A method for embedding a magnetic inductor in a substrate layer, the method comprising:
creating a structure within the substrate layer that identifies a defined region within the substrate layer;
inserting a magnetic paste into the defined region; and
wherein the structure is to contain the magnetic paste within the defined region while the magnetic paste cures.

9. The method of claim 8, wherein the substrate layer includes one or more conductive features; and
wherein the magnetic paste is to physically contact only a subset of the one or more conductive features that are within the defined region.

10. The method of claim 9, wherein the conductive features include a winding inductor structure or part thereof.

11. The method of claim 8, wherein creating a structure within the substrate layer further comprises:
applying a dielectric layer in the substrate layer; and
creating a cavity within the dielectric layer, wherein the cavity is the defined region.

12. The method of claim 11, wherein the substrate layer includes a copper seed layer below the dielectric layer; and
wherein creating the cavity further includes laser drilling a portion of the dielectric layer to create the cavity.

13. The method of claim 12, further comprising removing the copper seed layer.

14. The method of claim 8, wherein creating the structure within the substrate further comprises:
creating a dam structure using inkjet printing.

15. The method of claim 14, wherein the dam structure includes a solder resist material; and further comprising curing or partially curing the dam structure with ultraviolet light.

16. The method of claim 8, further comprising removing the structure.

17. A method for embedding a magnetic inductor in a substrate layer, the method comprising:
applying a copper (Cu) layer to a portion of the substrate layer;
creating a structure in the substrate layer on top of at least part of the Cu layer to identify a defined region within the substrate layer;
inserting a magnetic paste into the defined region;
wherein the Cu layer identifies a side of the defined region; and
wherein the structure is to contain the magnetic paste within the defined region while the magnetic paste cures.

18. The method of claim 17, wherein creating a structure to contain the magnetic paste further comprises:
applying a dielectric layer in the substrate layer; and
creating a cavity within the dielectric layer, wherein the cavity is the defined region.

19. The method of claim 18, wherein creating the cavity further includes laser drilling a portion of the dielectric layer to create the cavity.

20. The method of claim 17, wherein creating the structure further comprises:
creating a dam structure above the Cu layer using inkjet printing, wherein the dam structure includes a solder resist material; and
curing or partially curing the dam structure using ultraviolet light.
